(19) United States
(12) Patent Application Publication
(10) Pub. No.: US 2008/0043544 A1
(43) Pub. Date: Feb. 21, 2008

(54) Memory device and method of improving the reliability of a memory device

(76) Inventors: Corvin Liaw, Munchen (DE); Milena Dimitrova, Unterhaching (DE); Michael Markert, Augsburg (DE); Stefan Dietrich, Tuerkenfeld (DE)

Correspondence Address: SLATER & MATSIL LLP, 17950 PRESTON ROAD, SUITE 1000, DALLAS, TX, 75252, US

(21) Appl. No.: 11/507,381

(22) Filed: Aug. 21, 2006

(51) Int. Cl. G11C 7/00

(52) U.S. Cl. 365/191

(57) ABSTRACT

A memory device comprises a memory cell array comprising a plurality of memory cells, bitlines being electrically connected to the memory cells of the memory cell array, amplifier circuits being electrically connected to the bitlines and amplifying electrical signals carried in the bitlines, the amplifier circuits being activated and deactivated by means of amplifier circuit control nodes, and at least one potential supplying unit, by means of which potentials can be supplied to the amplifier circuits such that, in the deactivated state of the amplifier circuits, a decrease or a prevention of leakage currents through the amplifier circuits is caused.

### TECHNICAL FIELD

The invention relates to a memory device and to a method of improving the reliability of a memory device. The invention further relates to a resistive memory device, an amplifier circuit and a computer program product.

### BACKGROUND

Semiconductor devices are used for integrated circuits in a variety of electrical and electronic applications, such as computers, cellular telephones, radios, and televisions. One particular type of semiconductor device is a semiconductor storage device, such as a random access memory (RAM) device. RAM devices use an electrical charge to store information. Many RAM devices include many storage cells arranged in a two-dimensional array with two sets of select lines, wordlines and bitlines. An individual storage cell is selected by activating its wordline and its bitline. RAM devices are considered “random access” because any memory cell in an array can be accessed directly if the row and column that intersect at that cell are known.

A commonly used form of RAM is known as a dynamic RAM device. Dynamic random access memory (DRAM) has memory cells with a paired transistor and capacitor. As a dynamic memory, the DRAM must be refreshed to retain its information. A static random access memory (SRAM), which may include six transistors, will retain its state as long as power remains to the device. To retain memory even without power a non-volatile memory must be used. Examples of non-volatile memories include conductive bridging random access memory (CBRAM), magnetoresistive random access memory (MRAM), and plated chalcogenide random access memory (PCRAM).

It is desirable to improve the reliability of memory devices.

### SUMMARY OF THE INVENTION

According to one embodiment of the invention a memory device is provided, the memory device comprising a memory cell array comprising a plurality of memory cells, bitlines being electrically connected with the memory cells of the memory cell array, amplifier circuits being electrically connected with the bitlines and amplifying electrical signals carried in the bitlines, wherein the amplifier circuits are activated and deactivated by means of amplifier circuit control nodes, and at least one potential generating device by means of which the control nodes can be set to potentials, which cause a decrease or prevention of leakage currents through the amplifier circuits in the deactivated state of the amplifier circuits.

### BRIEF DESCRIPTION OF THE DRAWINGS

In the following, exemplary embodiments of the invention are explained in more detail with reference to the figures. In the figures:

FIG. 1 shows a schematic illustration of a part of an embodiment of a memory device;

FIG. 2 shows a schematic illustration of a part of an embodiment of a memory device;

FIG. 3 shows a schematic illustration of a part of an embodiment of the memory device according to the invention;

FIG. 4 shows a schematic flow chart of an embodiment of the method according to the invention;

FIG. 5 shows a circuit diagram of a part of an embodiment of a memory device;

FIG. 6 shows current and voltage curves in the bitlines of the embodiment shown in FIG. 5;

FIG. 7 shows a circuit diagram of an embodiment of the amplifier circuit according to the invention;

FIG. 8 shows a circuit diagram of an embodiment of the amplifier circuit according to the invention;

FIG. 9 shows time lapses of currents and voltages in the bitlines of an embodiment of the memory device according to the invention;

FIG. 10 shows time lapses of currents and voltages in the bitlines of an embodiment of the memory device according the invention;

FIG. 11 shows a circuit diagram of a part of an embodiment of the memory device according to the invention; and

FIG. 12 shows a schematic illustration of a part of an embodiment of the memory device according to the invention.

### DETAILED DESCRIPTION OF ILLUSTRATIVE EMBODIMENTS

According to one embodiment of the invention a memory device is provided, including a memory cell array including a plurality of memory cells, bitlines being electrically connected with the memory cells of the memory cell array, amplifier circuits being electrically connected with the bitlines and the amplifying electrical signals carried within the bitlines, wherein the amplifier circuits are activated and deactivated by means of amplifier circuit control nodes, and at least one potential supplying unit, by means of which potentials can be supplied to the amplifier circuits such that, in the deactivated state of the amplifier circuits, a decrease or a prevention of leakage currents through the amplifier circuits is caused.

According to one embodiment of the invention the amplifier circuits amplify memory cell readout signals.

According to another embodiment of the invention each amplifier circuit is electrically connected with two adjacent bitlines.

According to another embodiment of the invention each amplifier circuit is arranged within a bitline pitch.

According to another embodiment of the invention the memory device includes a write circuit for writing the memory cells, the write circuit being electrically connected with the bitlines.

According to another embodiment of the invention the amplifier circuits are arranged between the write circuit and the memory cell array.

According to another embodiment of the invention the amplifier circuits are electrically connected with parts of the bitlines, which run between the write circuit and the memory cell array.

According to another embodiment of the invention a multiplexer is connected inbetween the write circuit and the amplifier circuits, the multiplexer being electrically connected with the bitlines.

According to another embodiment of the invention the control nodes of each amplifier circuit each include a positive activating node and a negative activating node, which serve for activating and deactivating the amplifier circuit.

According to another embodiment of the invention, during the write state the negative activating node can be set to the potential occurring on the bitlines during the write state, and during the write state the positive activating node can be set to the lowest potential occurring on the bitlines during the write state.

According to another embodiment of the invention, during the quiescent state the negative activating node can be set to the potential (or highest potential) occurring in the amplifier circuit, and during the quiescent state the positive activating node can be set to the lowest potential occurring in the amplifier circuit.

According to another embodiment of the invention during the write state and the idle (quiescent) state the negative activating node can be set to the potential occurring on the bitline during the write state, and during the write state and the idle state the positive activating node can be set to the lowest potential occurring on the bitlines during the write state.

According to another embodiment of the invention each amplifier circuit is connected with a first bitline and a second bitline being adjacent to the first bitline, wherein when writing a memory cell by means of the first bitline, the second bitline can be set to the potential occurring on the first bitline during the write state.

According to another embodiment of the invention a disconnecting device is provided, by means of which, during writing a memory cell, a part of the second bitline lying within the memory cell array can be disconnected from that part of the second bitline which is set to the potential occurring on the first bitline during the write state.

According to another embodiment of the invention each amplifier device includes several transistors being connected with one another, which transistors can be controlled by the potentials of the control nodes.

According to another embodiment of the invention the memory device is a resistive memory device and/or a non-volatile memory device.

According to another embodiment of the invention the memory device includes one of a CBRAM memory device, an MRAM memory device or a PCRAM memory device.

According to another embodiment of the invention a resistive memory device is provided, including a memory cell array, a write circuit for writing the memory cells, bitlines electrically connecting the memory cells of the memory cell array with the write circuit, and amplifier circuits amplifying the memory cell readout signals and being electrically connected with parts of the bitlines running between the memory cell array and the write circuit, wherein activating nodes of the amplifier circuits can be set to potentials, which decrease or prevent leakage currents through the amplifier circuits during the write state or the quiescent state of the memory device.

According to another embodiment of the invention an amplifier circuit is provided, which can be electrically connected with the bitlines of an array of non-volatile memory cells and which amplifies electrical signals carried in the bitlines, wherein the amplifier circuit is activated and deactivated by means of amplifier circuit control nodes, and wherein the amplifier circuit includes at least one potential supplying device, by means of which the control nodes can be set to potentials which decrease or prevent leakage currents through the amplifier circuits in the deactivated state of the amplifier circuits.

According to another embodiment of the invention the amplifier circuit amplifies memory cell readout signals.

According to another embodiment of the invention the amplifier circuit can be electrically connected with two adjacent bitlines.

According to another embodiment of the invention the amplifier circuit is arranged within a bitline pitch.

According to another embodiment of the invention a method of improving the reliability of a memory device is provided, the memory device including a memory cell array including a plurality of memory cells, bitlines being electrically connected with the memory cells of the memory cell array, and amplifier circuits being electrically connected with the bitlines and amplifying electrical signals carried in the bitlines, wherein the amplifier circuits are activated and deactivated by means of amplifier circuit control nodes, wherein the method includes the process that, during the deactivated state, the amplifier circuits (for example the control nodes) are set to potentials, which decrease or prevent leakage currents through the amplifier circuits in the deactivated state of the amplifier circuits.

According to another embodiment of the invention the amplifier circuits amplify memory cell readout signals.

According to another embodiment of the invention the control nodes of each amplifier circuit include a positive activating node and a negative activating node, wherein the activation and deactivation of the amplifier circuits is effected by setting the activating nodes to respective potentials.

According to another embodiment of the invention, during the write state the negative activating node is set to the potential (or highest potential) occurring on the bitlines during the write state, and during the write state the positive activating node is set to the lowest potential occurring on the bitlines during the write state.

According to another embodiment of the invention, during the quiescent state the negative activating node is set to the potential (or highest potential) occurring in the amplifier circuit, and during the idle state the positive activating node is set to the lowest potential occurring in the amplifier circuit.

According to another embodiment of the invention, during the write state and the idle state the negative activating node is set to the potential (or highest potential) occurring on the bitlines during the write state, and during the write state and the idle state the positive activating node is set to the lowest potential occurring on the bitlines during the write state.

According to another embodiment of the invention each amplifier circuit is electrically connected with a first bitline and a second bitline adjacent to the first bitline, wherein, when writing a memory cell by means of the first bitline, the second bitline is set to the potential occurring on the first bitline during the write state.

According to another embodiment of the invention, during writing a memory cell a part of the second bitline that lies within the memory cell array is disconnected from that part of the second bitline that is set to the potential occurring on the first bitline during the write state.

According to another embodiment of the invention the amplifier circuits are voltage amplifier circuits, that is, reading the memory states of a memory cell is effected by measuring an electrical voltage applied to the respective bitline, wherein the voltage takes on different values in dependence on the memory states of the memory cell. The voltage applied to the bitline is amplified by a corresponding voltage amplifier circuit. The invention can analogously be applied to memory devices that detect the memory states of a memory cell by means of electrical measurement currents carried in the bitlines. In this case current amplifier circuits amplify the electric currents carried in the bitlines.

According to another embodiment of the invention a computer program product is provided, the computer program product being designed for executing a method of improving the reliability of a memory device, when being executed on a computer or a DSP, wherein the memory device includes a memory cell array including a plurality of memory cells, bitlines being electrically connected with the memory cells of the memory cell array, and amplifier circuits, being electrically connected with the bitlines and amplifying electrical signals carried in the bitlines, wherein the amplifier circuits are activated and deactivated by means of amplifier circuit control nodes, wherein the method includes the process, that during the deactivated state, the amplifier circuits are set to potentials that decrease or prevent leakage currents through the amplifier circuits in the deactivated state.

The invention further provides a data storage medium that stores the computer program product according to the invention.

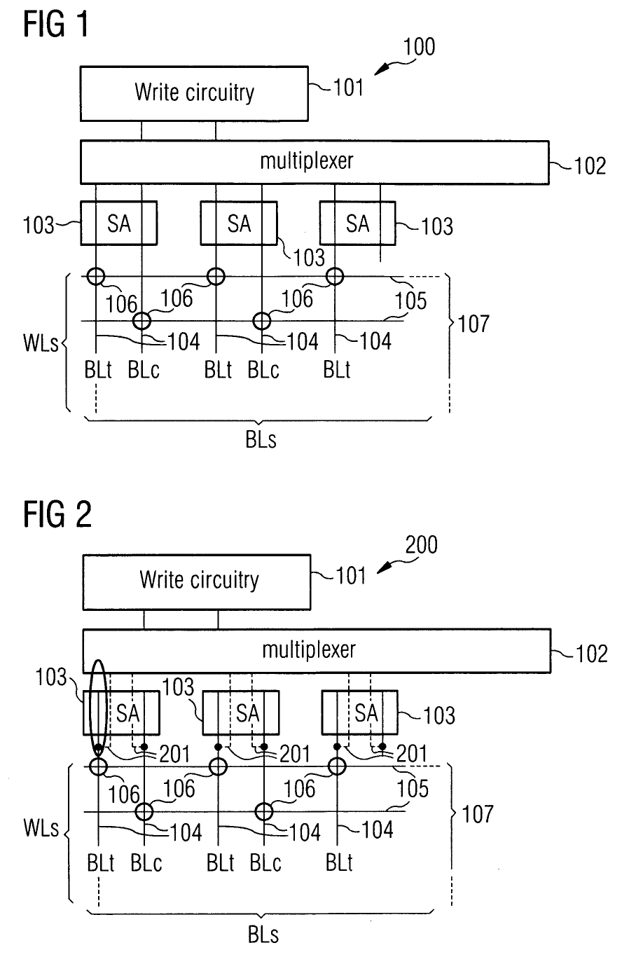

FIG. 1 shows one embodiment of a memory device 100, which includes a write circuit 101, a multiplexer 102, amplifier circuits 103, bitlines 104, wordlines 105 and memory cells 106. The bitlines 104 form an electrical connection between the memory cells 106 and the multiplexer 102, and moreover are electrically connected with the amplifier circuits 103. The memory cells 106 are formed in the region of the cross-points between the bitlines 104 and the wordlines 105. The memory cells 106 are arranged as a memory cell array 107. The amplifier circuits 103 are arranged between the memory cell array 107 and the multiplexer 102. The write circuit 101 is electrically connected with the multiplexer 102.

In order to write a memory cell 106, the write circuit 101 generates a corresponding memory cell write signal, which, by means of the multiplexer 102, is passed to one of the bitlines 104, which is electrically connected with the memory cell 106 to be written, and which write signal is carried to the memory cell in the bitline. Memory cell readout signals, which are generated when reading the memory state of the written memory cell, are carried in the same bitline that is also used for writing the memory cell. The memory cell readout signals are amplified by means of the amplifier circuits 103. Both the memory cell write signals and the memory cell read signals thus pass the amplifier circuits 103, that is, the memory cell write signals have to pass through the amplifier circuits 103, although these are not at all required for the writing process of the memory cells 106 (the amplifier circuits 103 usually are deactivated during the write state and the quiescent state, during the reading process however they are activated).

One disadvantage of the embodiment of the memory device 100 is that, during the write state of the memory device, that is in the deactivated state of the amplifier circuits 103, leakage currents can occur in the amplifier circuits 103 (leakage currents, that, starting from the bitlines 104, flow right through the amplifier circuits 103 to adjacent bitlines 104 or amplifier circuit control nodes). The leakage currents have the effect that the strength of the memory cell write signals lies below predetermined nominal values, which in turn impairs the operational reliability of the memory device 100.

In order to avoid the above-described disadvantage, electrical connections 201 can be provided, as is realized in the memory device 200 shown in FIG. 2, wherein each electrical connection 201 connects a bitline 104 with the multiplexer 102. The electrical connections 201 bypass the amplifier circuits 103, that is no direct electrical coupling exists between the electrical connections 201 and the amplifier circuits 103. By using the electrical connections 201 it is thus possible to carry the memory cell write signals “around” the amplifier circuits 103, thereby being able to avoid the above-mentioned leakage currents during the write state of the memory device 200. However, since the electrical connections 201 are indirectly electrically coupled with the amplifier circuits 103 via the bitlines 104, the amplifier circuits 103 should be separated from the bitlines 104 and thus from the electrical connections 201 during the write state via switching elements not shown in FIG. 2.

One advantage of the memory device 200 shown in FIG. 2 is that, by the prevention of leakage currents, the strength of the memory cell write signals can be kept at corresponding nominal values, which provides for a high operational reliability of the memory device 200. One disadvantage though is that, in the region of the amplifier circuits 103 the number of conductors running in parallel is doubled (bitlines 104 as well as electrical connections 201), which limits the miniaturization of the memory device 200. Furthermore it is not possible to accommodate each of the amplifier circuits 103 within one bitline pitch, since this is “transected” by the electrical connections 201.

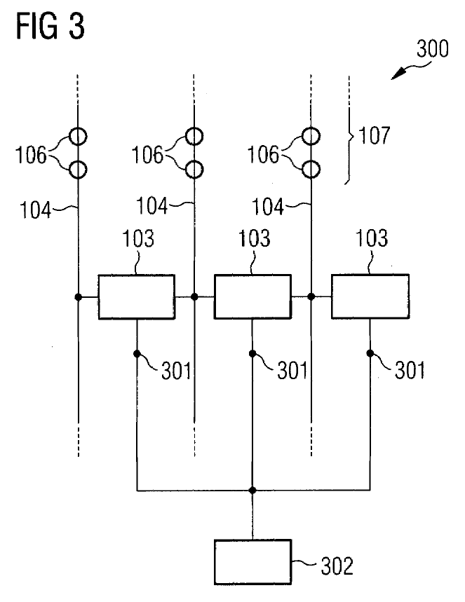

FIG. 3 shows one embodiment of a memory device 300 according to the invention. A memory device 300 includes a memory cell array 107 with a plurality of memory cells 106, bitlines 104 being electrically connected with the memory cells 106 of the memory cell array 107, amplifier circuits 103 being electrically connected with the bitlines 104 and amplifying electrical signals carried in the bitlines 104. The amplifier circuits 103 can be activated and deactivated by means of amplifier circuit control nodes 301. The memory device 300 includes at least one potential generating device 302, which is electrically connected with the amplifier circuit control nodes 301 and which sets the potentials applied to the amplifier circuit control nodes 301 in such a way that a decrease or prevention of leakage currents through the amplifier circuits 103 can be effected in the deactivated state of the amplifier circuits 103.

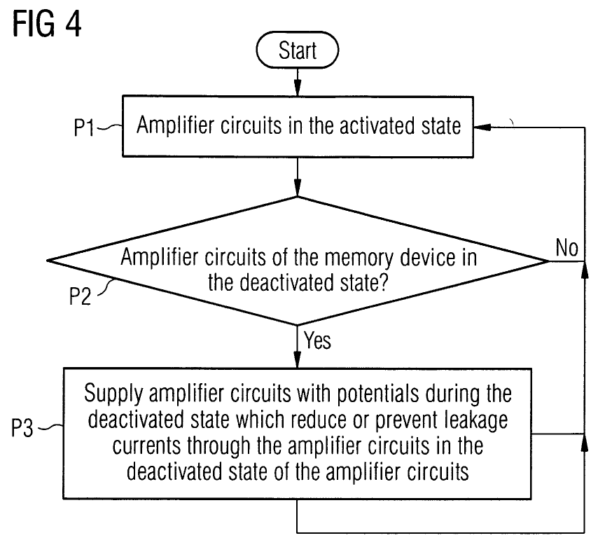

FIG. 4 shows one embodiment of a method of improving the reliability of a memory device according to the invention. In a first process P1 the operating state of the memory device is monitored by determining (for example in regular time intervals) in a second process P2 whether the amplifier circuits of the memory device are in a deactivated state. If this is the case, then in a third process P3 the amplifier circuit control nodes, during the deactivated state, are set to potentials, which decrease or prevent leakage currents through the amplifier circuits in the deactivated state of the amplifier circuits. Afterwards the method returns to the first process P1. If the amplifier circuits of the memory device are in the activated state then the method returns to the first process P1.

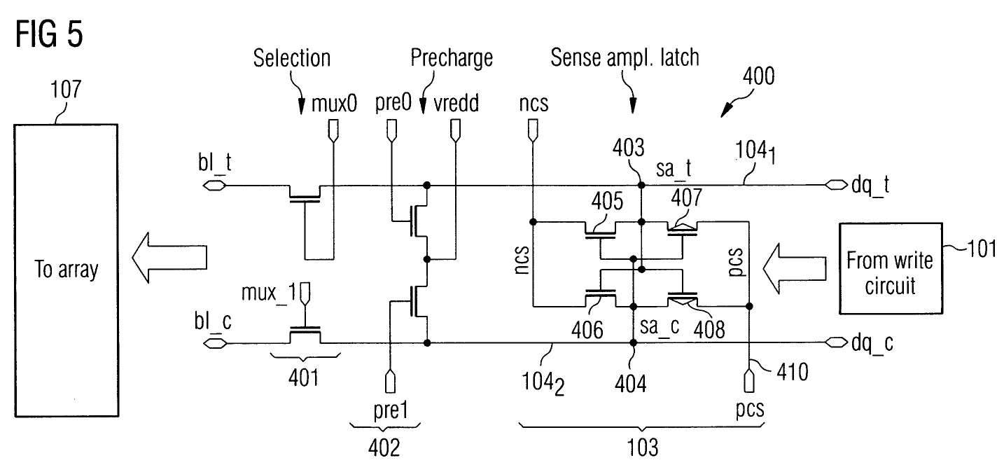

FIG. 5 shows a schematic illustration of a part of an embodiment of the memory device according to the invention. A memory device 400 includes a memory cell array 107, a write circuit 101 for writing the memory cells of the memory cell array 107, bitlines 104 electrically connecting the write circuit 101 with the memory cell 107, amplifier circuits 103 being electrically connected with the bitlines 104 and amplifying electrical signals carried in the bitlines 104, select circuits 401 as well as charging circuits 402 (in order to charge the bitlines 104 to a specified voltage). In FIG. 5, a first bitline 104, is shown as well as a second bitline 1042, representing adjacent bitlines. The amplifier circuit 103 shown in FIG. 5 is connected with the first bitline 104₁ via a first node 403. The amplifier circuit 103 is connected with the second bitline 104₂ via a second node 404. The amplifier circuit 103 includes a first NMOS transistor 405, a second NMOS transistor 406, a first PMOS transistor 407 as well as a second PMOS transistor 408. The source-drain ends of the first NMOS transistor 405 as well as of the second NMOS transistor 406 are connected with a first amplifier circuit control node 409 (in the following also referred to as a negative activating node). The source-drain ends of the first PMOS transistor 407 as well as of the second PMOS transistor 408 are connected with a second amplifier circuit control node 410 (in the following also referred to as a positive activating node). The first node 403 is connected with the gate of the second NMOS transistor 406 as well as with the gate of the second PMOS transistor 408. The second node 404 is connected with the gate of the first NMOS transistor 405 as well as with the gate of the first PMOS transistor 407. The source-drain ends of the first NMOS transistor 405 as well as of the first PMOS transistor 407 are connected with the first node 403. The source-drain ends of the second NMOS transistor 406 as well as of the second PMOS transistor 408 are connected with the second node 404.

The amplifier circuit 103 can be interpreted as a concatenation of two inverters, the input terminal of the first inverter being connected to the output terminal of the second inverter, and the input terminal of the second inverter being connected to the output terminal of the first inverter. If the first node 403 exhibits a potential that is higher than a certain potential threshold value (“high”), the amplifier circuit 103 will output a high voltage signal. If the potential of the first node 403 lies below a certain threshold value (“low”), then the amplifier circuit 103 will output a low voltage signal. The same holds in an analogous manner for the second node 404.

The amplifier circuit 103 is activated and deactivated by means of the potentials of the negative activating node 409 as well as the positive activating node 410. Since the amplifier circuit 103 shall merely amplify the memory cell readout signals (that is, the signals that are carried in the bitlines 104 during the read mode of the memory device 400), the amplifier circuit 103 is deactivated during the write state or the quiescent state. The potentials of the first node 403 as well as of the second node 404, however, can have the effect that the first NMOS transistor 405, the second NMOS transistor 406, the first PMOS transistor 407 or the second PMOS transistor 408 become conducting, such that leakage currents can occur between the first bitline 104₁ and the second bitline 104₂ or between one of the bitlines 104 and the negative activating node 409 or the positive activating node 410, that is leakage currents flow through the amplifier circuit 103. Such leakage currents are undesirable, since they tamper the memory cell write signals carried in the bitlines 104.

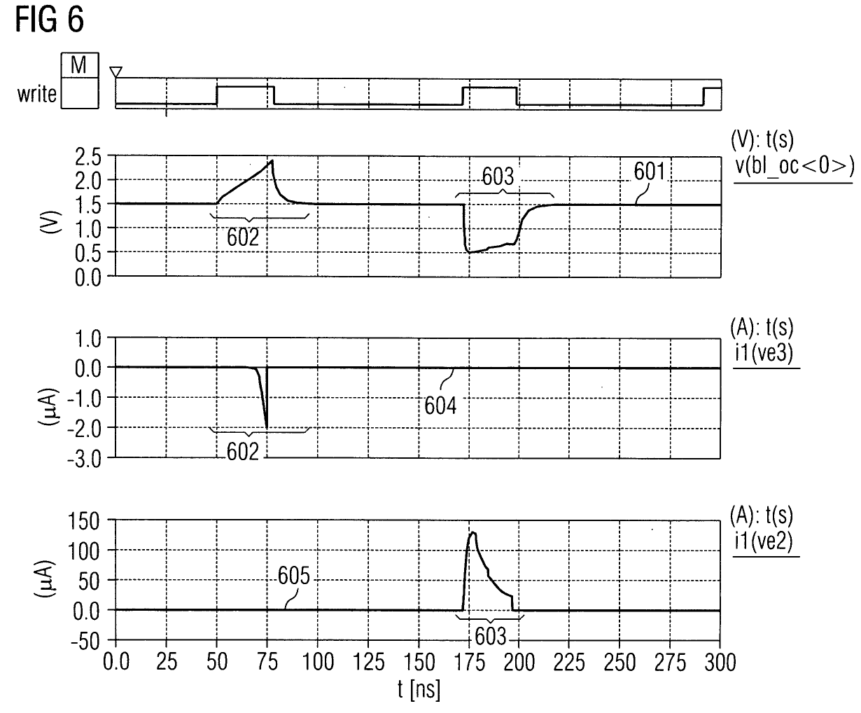

In the case that leakage currents occur, then voltage and current diagrams such as those shown in FIG. 6 result. The voltage curve 601 shows that during an erase operation 602 and during a programming operation 603 the voltage 601 occurring in the corresponding bitline does not reach the voltage target values (erase operation: 3 volts; programming operation: 0 volts). Current curve 604 and current curve 605 show corresponding leakage currents occurring at the transistors within the amplifier circuits 103. The current and voltage curves shown in FIG. 6 can for example occur when the negative activating node 409 and the positive activating node 410 are on the same potential, for example on the VPL potential.

In order to prevent the above-mentioned leakage currents, in one embodiment of the invention the potentials of the negative activating node 409 as well as of the positive activating node 410 are chosen in such a way that, during the write and quiescent states, the thereby resulting voltages are opposite to the voltages that result when the negative activating node 409 and the positive activating node 410 are set to the normally-used activating potentials. In other words, during the write and quiescent states of the memory device, the positive activating node 410 is set to the lowest potential occurring in the amplifier circuit, and during the write and quiescent states the negative activating node 409 is set to the highest potential occurring in the amplifier circuit 103. In this example, the negative activating node 409 is set to 1.5 volts, and the positive activating node 410 is set to 0 volts.

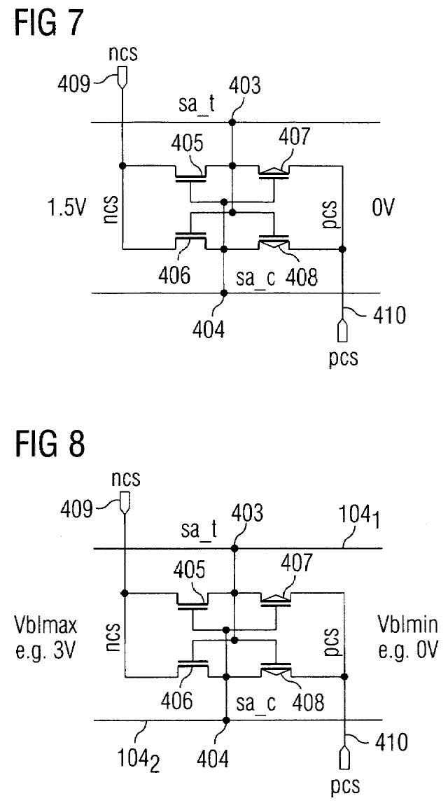

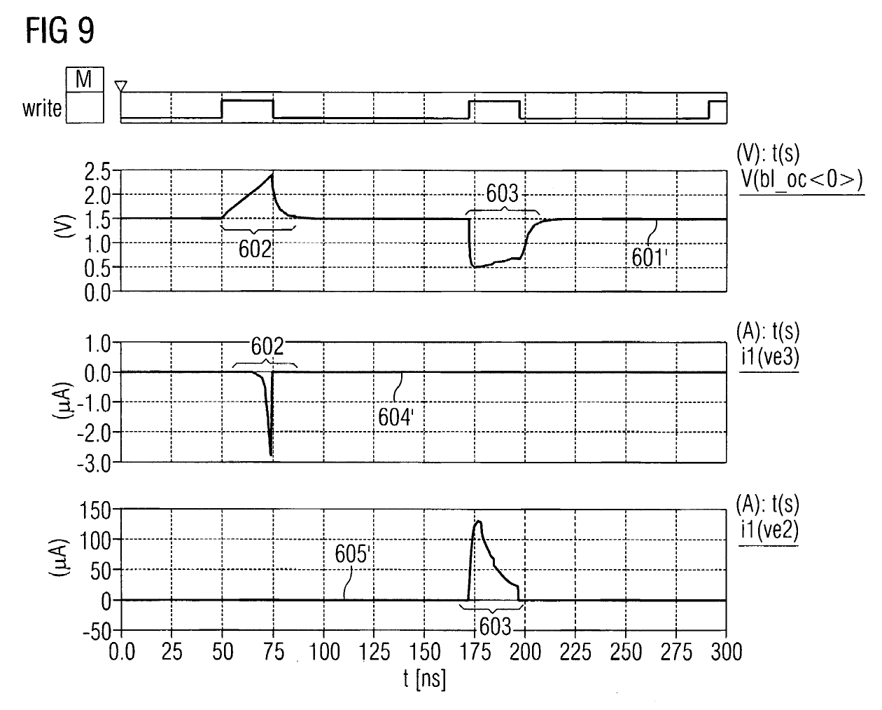

Although the embodiment shown in FIG. 7 prevents leakage currents during the quiescent state of the memory device, leakage currents during the write state of the memory device cannot be prevented with this embodiment, as is shown by the current and voltage curves 601′, 604′ and 605′ in FIG. 9.

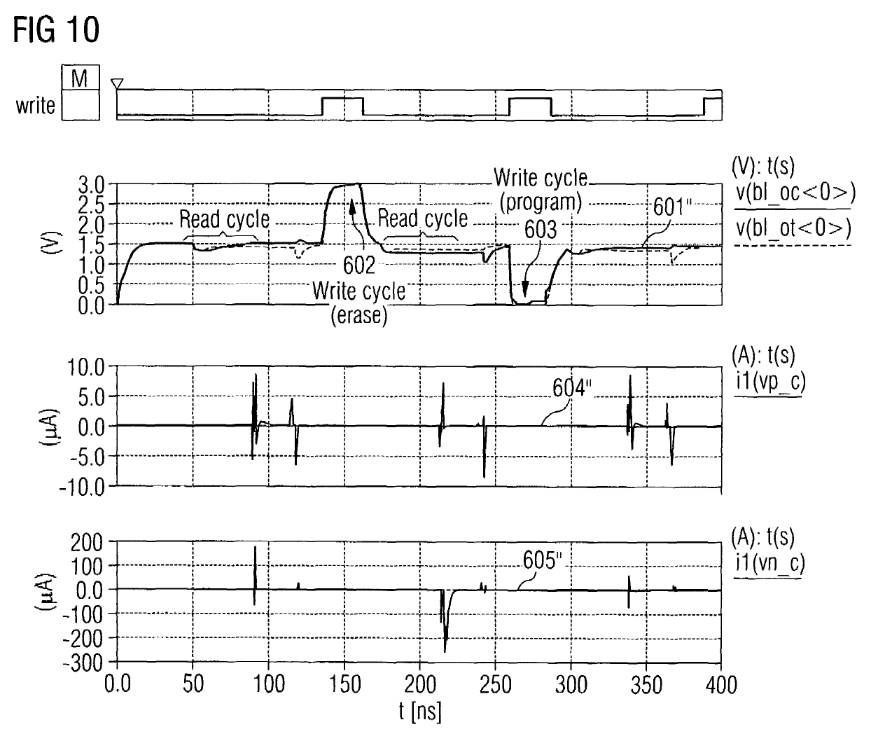

FIG. 8 shows an embodiment of the memory device according to the invention, in which the potential of the positive activating node 410 is set to the lowest potential occurring on the bitlines 104 during the write state, and in which the potential of the negative activating node 419 is set to the highest potential occurring on the bitlines 104 during the write state. If, in addition, also the bitline 104 that is not involved in the write process, that is the first node 403 or the second node 404, is set to the write potential, then the leakage current curves and voltage curves 601″, 604″ and 605″ shown in FIG. 10 result. As can be seen from FIG. 10, the voltages as well as the electric currents during the erase operations 602 as well as the programming operations 603 meet the specified nominal values.

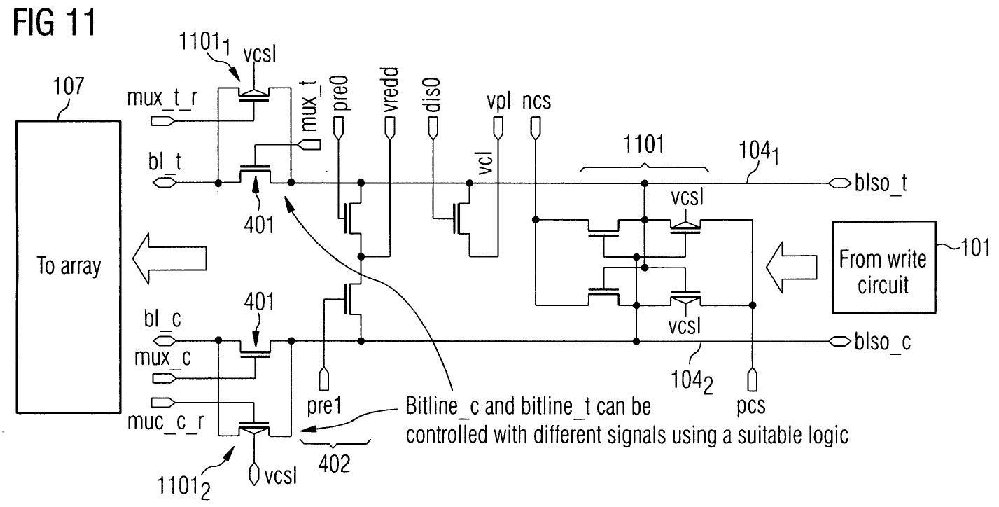

FIG. 11 shows an embodiment of the memory device according to the invention. The memory device 1100 essentially corresponds in its architecture to the memory device 400 shown in FIG. 5. In addition, each bitline 104 is provided with a disconnecting device 1101, by means of which the respective bitline 104 can be electrically disconnected from the memory cell array 107. In this way it is possible on the one hand to bring both the first bitline 104₁ as well as the second bitline 104₂ to the write potential during the quiescent or write state of the memory device 1100, in order to prevent leakage currents, on the other hand, however, to avoid high voltages on the bitlines not required for writing the memory cells within the memory cell array 107.

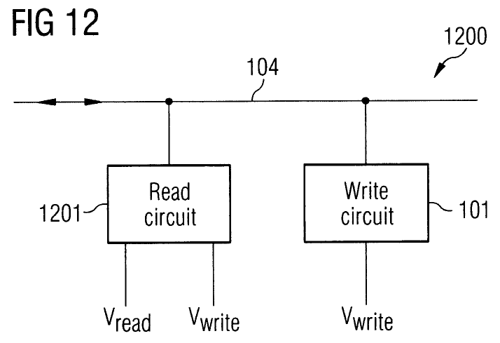

FIG. 12 shows an embodiment of the memory device 1200 according to the invention. The memory device 1200 includes a bitline 104, a read circuit 1201 and a write circuit 101, wherein the bitline 104 is electrically connected with the read circuit 1201 and the write circuit 101. The write circuit 101 writes a memory cell connected to the bitline 104 (not shown here) by means of a write voltage V_{write}, which for this purpose is supplied to the write circuit 101. The read circuit 1201 reads the memory state of a memory cell (not shown here) connected to the bitline 104 by means of a read voltage V_{read}, which for this purpose is supplied to the read circuit 101 (which, for example, includes an amplifier circuit 103 and optionally a potential generating device 302 as shown in FIG. 3). In addition to the read voltage V_{read} the read circuit 101 is also supplied with the write voltage V_{write}, by means of which the control nodes of an amplifier circuit that is part of the read circuit 1201, can be set to the write voltage V_{write}. In this way, leakage currents through the read circuit 1201 can be prevented or decreased. The arrangement shown in FIG. 12 is not restricted to one bitline 104, one read circuit 1201 and one write circuit 101. Several bitlines 104, read circuits 1201 and write circuits 101 maybe used.

In the following description further aspects of exemplary embodiments of the invention will be described.

When combining write circuits for CBRAM memory cells or for other resistive memory cells with voltage read circuits, which can be arranged within the bitline pitch, unintentional leakage currents result during the write cycles. These leakage currents have the effect that neither is the full write voltage applied to the memory cell nor can the preset write current flow through the memory cell.

By appropriate choice of the voltages applied to the voltage amplifier transistors all transistors can be kept non-conducting during the write operation.

Thus the following advantages result:

a) The write circuit can be combined with read circuits, which can be integrated in the bitline pitch.

b) The write voltage can be adjusted exactly.

c) Leakage currents that tamper the write currents can be effectively eliminated or decreased, thereby making the write conditions reproducible. In this way both endurance and data retention can be improved.

One embodiment of the invention is based on applying voltages to the voltage amplifier transistors, which voltages for the operating condition(s) write (and quiescent state) prevent that they become conducting. For that purpose according to one embodiment of the invention the negative activating node of the voltage amplifier transistors (in the quiescent (idle) state and) during the writing is brought not only to the positive supply voltage but to the highest potential occurring on the bitlines during a write operation. The positive activating node at the same time is kept at the lowest voltage occurring during the write operation. Moreover, usually it is not sufficient to apply the required write voltage only to the bitline of the cell to be written. Also the bitline, which is connected with the same voltage read amplifier (or at least with the associated amplifier node) in a complementary manner to the written bitline, should be charged with the same write voltage.

FIG. 1 shows an advantageous arrangement for the combination of a voltage read circuit and a write circuit. In this arrangement the voltage read amplifiers (SA) are directly connected with the bitlines (BLt and BLc). A multiplexer can switch the write circuit to the selected bitline, which is led through the voltage read amplifier. Since the read amplifier transistors are directly connected with the bitlines, leakage currents can occur during the write operation that prevent the write operation or at least make a precise writing of the cells impossible.

FIG. 2 shows an arrangement of a voltage amplifier and a write circuit that would enable an undisturbed write access to the memory cells. Here, the bitline is led directly to the write multiplexer in parallel to the voltage amplifier. If now writing occurs, then the write multiplexer can connect the write circuit directly with the selected bitline. The voltage amplifier can be disconnected from the bitline by means of a select switch (not shown), thereby enabling an undisturbed writing. One disadvantage of this circuit is the doubling of the conductive lines in the region of the voltage amplifiers. Due to this doubling of the conductive lines the voltage amplifiers can no longer be implemented within the bitline pitch, such that each voltage amplifier is no longer connected with only one bitline pair; an additional select switch is required. At this place the essential advantage of the arrangement shown in FIG. 1 becomes clear. In this arrangement the read amplifiers can be accommodated in the bitline pitch, and only in a pitch-fine grouping of the voltage amplifiers all bits along a wordline can be read at once. This read mode corresponds to the read mode of DRAMs, thereby simplifying a mapping of DRAM applications (e.g., prefetch, page mode).

FIG. 5 shows a detailed view of a voltage read amplifier in the arrangement of FIG. 1. On both sides of the amplifier, both in direction to the array and in direction to the read circuit, there are select transistors. In between, there are both the actual read amplifier latch and diverse precharge transistors, which are required for the read operation, but which can be completely switched off during the writing. The transistors of the read amplifier latch can become conducting and can cause the mentioned leakage currents.

FIG. 6 shows a simulation of the write operation for both activating nodes (ncs and pcs) being on a uniform potential, as it is usual in DRAM. During the write operation with a high voltage on the bitline bl_oc<0> and during the write operation with a lower voltage on the bitline bl_oc<0> leakage currents flow, and the voltages cannot reach their values required for the write operation (here 3 V and 0 V).

An improvement of the turn-off conditions of the transistors for the quiescent state can be realized in that the activating nodes of the read amplifier are respectively brought to the inverse supply voltage of the voltage amplifier, as it is shown in FIG. 7 (positive supply voltage of the read amplifier 1.5 V on the node ncs and negative supply voltage 0 V on the node pcs). As can be seen from FIG. 9, this also does not lead to an improvement of the write operations.

A thorough analysis of the problem leads to the conclusion that two effects lead to the conductivity of the transistors:

a) On the one hand the respective inverse supply voltage of the read amplifier activating nodes is not sufficient since, when writing, both voltages higher than the positive supply voltage and voltages lower than the negative supply voltage can be switched to the bitline.

b) On the other hand, the voltages of the nodes named sa_t and sa_c in FIG. 7 at the same time represent the gate voltage of the transistors, which cause the respective leakage currents. Since these nodes for the non-written bitline had been kept on a constant quiescent potential so far, at least one writing situation (or two if the quiescent potential is between the two writing values) arises, for which the transistor is increased. For this reason according to the invention during the write operation two operating conditions have to be provided for:

i) The two activating nodes of the read amplifier respectively have to be charged to the highest voltage occurring during writing (Vblmax) and to the lowest voltage occurring during writing (Vblmin) (FIG. 8).

ii) Both the node sa_t and the node sa_c have to acquire the corresponding value of the write voltage, independent of whether the bitline connected with sa_t or the bitline connected with sa_c shall be written.

Since, when the wordline is open, there is a memory cell only at every other bitline (cf. FIG. 1), the voltage can be switched to the complementary bitline without damage. In dependence on the memory cell architecture the way of switching may vary.

A simulation of the method according to the invention is shown in FIG. 10. Illustrated is the sequence read cycle—write cycle (high-ohmic)—read cycle—write cycle (low-ohmic)—read cycle. Here, both bitlines, the bitline bl_oc with the cell to be written as well as the complementary bitline bl_ot, are controlled with the respective write voltage. Since at the same time ncs is kept at Vblmax=3 V and pcs is kept at Vblmin=0 V, the full write voltage (3 V in the first write pulse and 0 V in the second write pulse) can be reached on the first bitline bl_oc. A current flow through the read amplifier transistors occurs only during the read cycle (in which the read amplifier is activated), during the write operation the leakage current is effectively prevented.

The voltages of the activating nodes can keep the mentioned values also in the quiescent state. In this way the switching back and forth of these nodes can be reduced.

A further variant of the invention is shown in FIG. 11. The multiplex transistors shown are separately controllable for the bitlines BL_C and the bitlines BL_T (cf. FIG. 1). If now, for example, cells at the bitlines BL_C are written, the corresponding multiplexers (switching elements) are opened. The multiplexers (switching elements) associated with the bitlines BL_C in contrast are closed. In this way the complementary node at the read amplifier can acquire the required voltage, without the bitline being reloaded (ungeladen). This can have advantageous effects on the current consumption and can prevent the possibly damaging impact on the cells, which, though not being selected, however are connected with the bitline via a closed transistor.

As used herein the terms “connected” and “coupled” are intended to include both direct and indirect connection and coupling, respectively.

The foregoing description has been presented for purposes of illustration and description. It is not intended to be exhaustive or to limit the invention to the precise form disclosed, and obviously many modifications and variations are possible in light of the disclosed teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined solely by the claims appended hereto.

What is claimed is:

1. A memory device comprising:
a memory cell array comprising a plurality of memory cells;
bitlines electrically connected to the memory cells of the memory cell array;
amplifier circuits electrically connected to the bitlines and amplifying electrical signals carried in the bitlines, the amplifier circuits being activated and deactivated by means of amplifier circuit control nodes; and
at least one potential supplying unit, by means of which potentials can be supplied to the amplifier circuits such that, in the deactivated state of the amplifier circuits, a decrease or a prevention of leakage currents through the amplifier circuits is caused.

2. The memory device as claimed in claim 1, wherein the amplifier circuits amplify memory cell readout signals.

3. The memory device as claimed in claim 1, wherein each amplifier circuit is electrically connected to two adjacent bitlines.

4. The memory device as claimed in claim 1, wherein each amplifier circuit is arranged within a bitline pitch.

5. The memory device as claimed in claim 1, further comprising a write circuit for writing the memory cells, the write circuit being electrically connected to the bitlines.

6. The memory device as claimed in claim 5, wherein the amplifier circuits are arranged between the write circuit and the memory cell array.

7. The memory device as claimed in claim 5, wherein the amplifier circuits are electrically connected to parts of the bitlines that are arranged between the write circuit and the memory cell array.

8. The memory device as claimed in claim 5, further comprising a multiplexer connected between the write circuit and the amplifier circuits, the multiplexer being electrically connected to the bitlines.

9. The memory device as claimed in claim 5, wherein the control nodes of each amplifier circuit comprise a positive activating node and a negative activating node for activating and deactivating the amplifier circuit.

10. The memory device as claimed in claim 9, wherein the memory device is configured such that during the write state, the negative activating node can be set to the potential occurring on the bitlines during the write state, and the positive activating node can be set to the lowest potential occurring on the bitlines during the write state.

11. The memory device as claimed in claim 9, wherein the memory device is configured such that during the idle state, the negative activating node can be set to the highest potential occurring in the amplifier circuit, and the positive activating node can be set to the lowest potential occurring in the amplifier circuit.

12. The memory device as claimed in claim 9, wherein the memory device is configured such that during the write state and the idle state, the negative activating node can be set to the potential occurring on the bitlines during the write state, and the positive activating node can be set to the lowest potential occurring on the bitlines during the write state.

13. The memory device as claimed in claim 5, wherein each amplifier circuit is connected with a first bitline and a second bitline adjacent to the first bitline, wherein, when writing a memory cell by means of the first bitline, the second bitline can be set to the potential occurring on the first bitline during the write state.

14. The memory device as claimed in claim 13, further comprising a disconnecting device, by means of which during writing the memory cell a part of the second bitline lying within the memory cell array can be electrically disconnected from the part of the second bitline that is set to the potential occurring on the first bitline during the write state.

15. The memory device as claimed in claim 13, wherein each amplifier device comprises several transistors connected with one another that can be controlled by the potentials of the control nodes.

16. The memory device as claimed in claim 1, the memory cell array comprises an array of resistive memory cells.

17. The memory device as claimed in claim 16, wherein the memory cells each comprise one of a CBRAM cell, an MRAM memory cell, or a PCRAM cell.

18. The memory device as claimed in claim 1, wherein the amplifier circuits comprise voltage amplifier circuits.

19. A resistive memory device, comprising:
a memory cell array;
a write circuit for writing the memory cells;
bitlines electrically connecting the memory cells of the memory cell array to the write circuit; and
amplifier circuits amplifying the memory cell readout signals and being electrically connected to parts of the bitlines arranged between the memory cell array and the write circuit, wherein the amplifier circuits can be set to potentials that decrease or prevent leakage currents through the amplifier circuits during the write state or the idle state of the memory device.

20. An amplifier circuit that can be electrically connected with bitlines and that amplifies electrical signals carried in the bitlines, wherein the amplifier circuit is activated and deactivated by means of amplifier circuit control nodes, the amplifier circuit comprising at least one potential supplying device, by means of which the control nodes can be set to potentials, that decrease or prevent leakage currents in the amplifier circuit in the deactivated state of the amplifier circuit.

21. The amplifier circuit as claimed in claim 20, wherein the amplifier circuit is configured such that it amplifies memory cell readout signals.

22. The amplifier circuit as claimed in claim 20, wherein the amplifier circuit is configured such that it can be electrically connected with two adjacent bitlines.

23. The amplifier circuit as claimed in claim 20, wherein the amplifier circuit is arranged within a bitline pitch.

24. The amplifier circuit as claimed in claim 20, wherein the amplifier circuit comprises a voltage amplifier circuit.

25. A method of operating a memory device, the method comprising:
providing a memory device comprising:
a memory cell array, comprising a plurality of memory cells;
bitlines being electrically connected with the memory cells of the memory cell array;
amplifier circuits being electrically connected with the bitlines and amplifying electrical signals carried in the bitlines, the amplifier circuits being activated and deactivated by means of amplifier circuit control nodes; and
supplying the amplifier circuits with potentials decreasing or preventing leakage currents through the amplifier circuits in the deactivated state of the amplifier circuits.

26. The method as claimed in claim 25, wherein the amplifier circuits amplify memory cell readout signals.

27. The method as claimed in claim 25, wherein the control nodes of each amplifier circuit comprise a positive activating node and a negative activating node, and wherein the activation and deactivation of the amplifier circuits is effected by setting the activating nodes to respective potentials.

28. The method as claimed in claim 27, wherein, during the write state the negative activating node is set to the potential occurring on the bitlines during the write state, and the positive activating node is set to the lowest potential occurring on the bitlines during the write state.

29. The method as claimed in claim 27, wherein, during the idle state, the negative activating node is set to the highest potential occurring in the amplifier circuit, and the positive activating node is set to the lowest potential occurring in the amplifier circuit.

30. The method as claimed in claim 27, wherein, during the write state and the idle state, the negative activating node is set to the potential occurring on the bitlines during the write state, and the positive activating node is set to the lowest potential occurring on the bitlines during the write state.

31. The method as claimed in claim 25, wherein each amplifier circuit is connected with a first bitline and a second bitline adjacent to the first bitline, and wherein, when writing a memory cell by means of the first bitline, the second bitline is set to the potential occurring on the first bitline during the write state.

32. The method as claimed in claim 25, wherein during writing the memory cell, a part of the second bitline that lies within the memory cell array is separated from the part of the second bitline that is set to the potential occurring on the first bitline during the write state.

33. The method as claimed in claim 25, wherein the amplifier circuits comprise voltage amplifier circuits.

34. A computer program product, being designed for carrying out a method of improving the reliability of a memory device when being executed on a computer or a digital signal processor, the memory device comprising:
a memory cell array, comprising a plurality of memory cells;
bitlines, being electrically connected with the memory cells of the memory cell array; and
amplifier circuits, being electrically connected with the bitlines and amplifying electrical signals carried in the bitlines, wherein the amplifier circuits are activated and deactivated by means of amplifier circuit control nodes,
the method comprising:
during the deactivated state, setting the amplifier circuits to potentials which decrease or prevent leakage currents through the amplifier circuits in the deactivated state.

35. A data storage medium, which stores a computer program according to claim 34.
